(19) United States
(12) Patent Application Publication
(10) Pub. No.: US 2026/0107413 A1
(43) Pub. Date: Apr. 16, 2026

(54) SILENCING STRUCTURE AND SERVER HAVING THE SAME

(71) Applicant: COMPAL ELECTRONICS, INC., Taipei City (TW)

(72) Inventors: Ken-Ping Lin, Taipei City (TW); Chih-Hao Kuo, Taipei City (TW); Shih-Feng Yang, Taipei City (TW); Jing-Sian Wang, Taipei City (TW)

(73) Assignee: COMPAL ELECTRONICS, INC., Taipei City (TW)

(21) Appl. No.: 19/089,030

(22) Filed: Mar. 25, 2025

(30) Foreign Application Priority Data
Oct. 15, 2024 (TW) 113211145

(51) Int. Cl. H05K 7/20

(52) U.S. Cl. CPC H05K 7/20172; H05K 7/20145; H05K 7/20736

(57) ABSTRACT

A silencing structure includes a fan module, a silencing body and a silencing cover. The silencing body has a first partition and a neck partition, and the neck partition is connected to the fan module. The silencing cover is disposed in the silencing body and has a second partition and a fixed plate. The fan module, the silencing body and the silencing cover are surrounded to form a sound channel. The fixed plate covers the first partition. A resonance cavity is constituted by the second partition, fixed plate, and first partition. A neck opening is formed between the second partition and the neck partition, and the neck opening is communicated with the resonance cavity and the sound channel.

### CROSS-REFERENCE TO RELATED APPLICATION

This application claims the priority benefit of Taiwan application serial no. 113211145, filed on Oct. 15, 2024. The entirety of the above-mentioned patent application is hereby incorporated by reference herein and made a part of this specification.

### BACKGROUND

### Technical Field

The present invention relates to a silencing structure, and particularly relates to a silencing structure suitable for a fan module.

### Related Art

Servers and supercomputers need to operate for long periods of time and have powerful computing performance. Therefore, servers and supercomputers generate a large amount of waste heat during operation. Accumulated waste heat may lead to reduced computing performance, overheating shutdown, or even component burnout. Therefore, cooling efficiency is a key factor in whether servers, supercomputers, and other computing devices can operate smoothly. Existing technology arranges multiple sets of cooling fan arrays at the air vents of servers and supercomputers to draw in cold air and exhaust hot air to achieve cooling purposes.

However, cooling fans generate noise during operation, which affects other components in servers and supercomputers. For example, hard drives may develop bad tracks due to noise. Noise also affects the hearing of users or staff. Therefore, how to improve the noise problem of cooling fans has become an important issue.

### SUMMARY

The present invention provides a silencing structure to reduce the noise generated by the fan module when operating.

The silencing structure of the present invention includes a fan module, a silencing body, and a silencing cover. The silencing body has a first partition and a neck partition, the neck partition is connected to the fan module. The silencing cover is disposed on the silencing body and has a second partition and a fixed plate. The fan module, silencing body, and silencing cover surround to form a sound channel. A resonance cavity is constituted by the second partition, fixed plate, and first partition. A neck opening is formed among the second partition and the neck partition, and the neck opening is communicated with the resonance cavity and the sound channel.

In one embodiment of the present invention, the neck opening is vertical to an extending direction of the sound channel and an axial direction of the fan module.

In one embodiment of the present invention, the neck opening surrounds the sound channel.

In one embodiment of the present invention, the axial direction of the fan is parallel to the extending direction.

In one embodiment of the present invention, the fixed plate covers the first partition.

In one embodiment of the present invention, the distance between the neck opening and the fan module is not greater than the thickness of the neck partition.

In one embodiment of the present invention, the cross-section of the first partition and the neck partition in an X direction is L-shaped, and the cross-section of the second partition and the fixed plate in the X direction is L-shaped.

In one embodiment of the present invention, the silencing body and the silencing cover is a U-shaped structure in a Z direction.

In one embodiment of the present invention, the sound channel extends along the Z direction.

In one embodiment of the present invention, the neck opening surrounds the sound channel.

In one embodiment of the present invention, the silencing cover and the silencing body are disposed at a side opening of the fan module.

In one embodiment of the present invention, further including heat dissipation fins, disposed on the silencing cover and aligned with the sound channel.

In one embodiment of the present invention, the neck opening is vertical to an extending direction of the sound channel and a radial direction of the fan.

In one embodiment of the present invention, the neck opening surrounds the sound channel.

In one embodiment of the present invention, the axial direction of the fan is vertical to the extending direction.

In one embodiment of the present invention, the silencing cover or the silencing body has an L-shaped cross-section in a plane vertical to the axial direction of the fan.

In one embodiment of the present invention, the silencing cover or the silencing body has a square-shaped cross-section in a plane vertical to the extending direction.

The server of the present invention includes a chassis, at least one heat-generating component, and a plurality of silencing structures. The at least one heat-generating component is disposed inside the chassis. The plurality of silencing structures are arranged in a matrix or stacked in a matrix inside the chassis, and partially or completely correspond to the at least one heat-generating component.

Based on the above, the silencing structure of the present invention is suitable for the existing fans. By controlling the cross-sectional area of the resonance cavity and the length of the neck opening, the resonance frequency of the silencing structure may approach the vibration frequency of the noise. When noise passes through the silencing structure, part of the noise enters the resonance cavity via the neck opening to produce energy attenuation, thereby reducing the sound energy during noise transmission and achieving the purpose of noise reduction.

In addition, the silencing structure of the present invention may be directly installed on existing fans without changing the orientation of cooling components in servers or supercomputers, thus having better versatility.

### BRIEF DESCRIPTION OF THE DRAWINGS

FIG. 1A is a three-dimensional schematic view of a silencing structure according to one embodiment of the present invention.

FIG. 1B is a cross-sectional schematic view of the silencing structure of FIG. 1A along segment A-A.

FIG. 1C is a side view schematic diagram of the silencing structure of FIG. 1A combined with a fan.

FIG. 1D is an exploded three-dimensional schematic view of the components of the silencing structure and fan of FIG. 1C.

FIG. 2A is a three-dimensional schematic view of another embodiment of the silencing structure of the present invention combined with a fan.

FIG. 2B is a cross-sectional schematic view of the silencing structure of FIG. 2A along segment B-B.

FIG. 2C is a plan view schematic diagram of the silencing structure of FIG. 2B.

FIG. 3A is a three-dimensional schematic view of another embodiment of the silencing structure of the present invention combined with a fan and heat dissipation fins.

FIG. 3B is a cross-sectional schematic view of the silencing structure of FIG. 3A along segment C-C.

FIG. 3C is a cross-sectional schematic view of the silencing structure of FIG. 3A along segment D-D.

FIG. 4 is a cross-sectional schematic view along segment C-C of another embodiment of the silencing structure of FIG. 3A.

FIG. 5A is a cross-sectional schematic view of another embodiment of the silencing structure of the present invention combined with a fan and heat dissipation fins.

FIG. 5B is a cross-sectional schematic view of the silencing structure of FIG. 5A combined with a first silencing body, a first silencing cover, a second silencing body, and a second silencing cover.

FIG. 6 is a cross-sectional schematic view of another embodiment of the silencing structure of the present invention combined with a fan and heat dissipation fins.

FIG. 7 is a cross-sectional schematic view of another embodiment of the silencing structure of the present invention combined with a fan and heat dissipation fins.

FIG. 8 is a cross-sectional schematic view of the silencing structure of FIG. 7 combined with a first silencing body, a first silencing cover, a second silencing body, a second silencing cover, and a plurality of washers.

FIG. 9 is a cross-sectional schematic view of another embodiment of the silencing structure of FIG. 2A along segment B-B.

### DESCRIPTION OF THE EMBODIMENTS

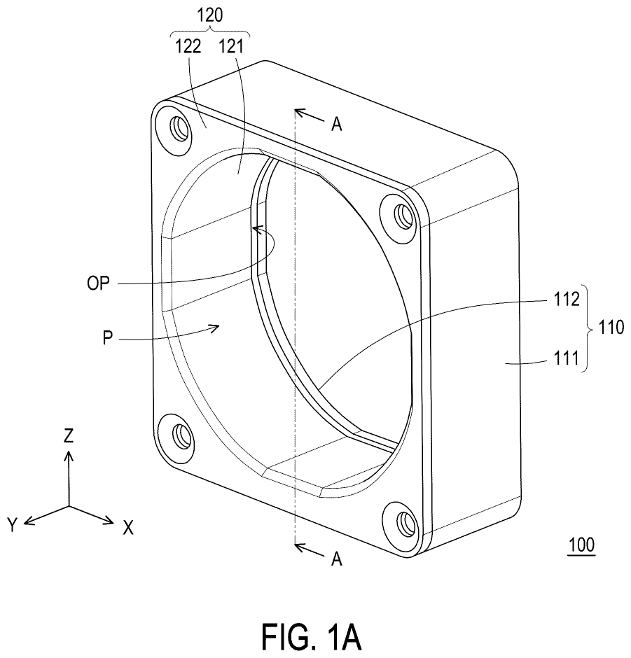

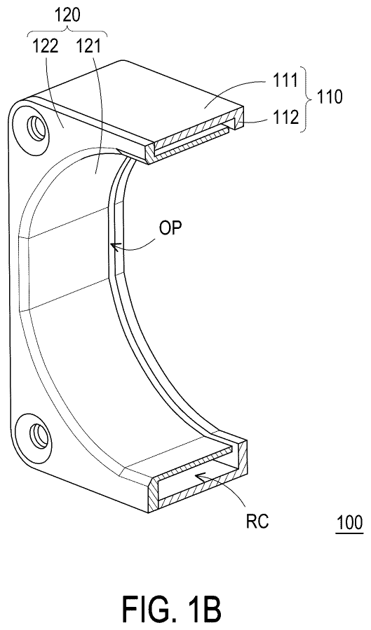

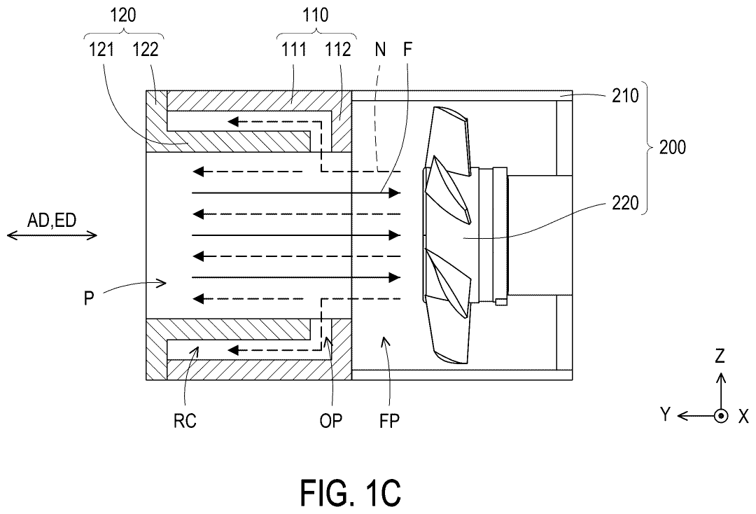

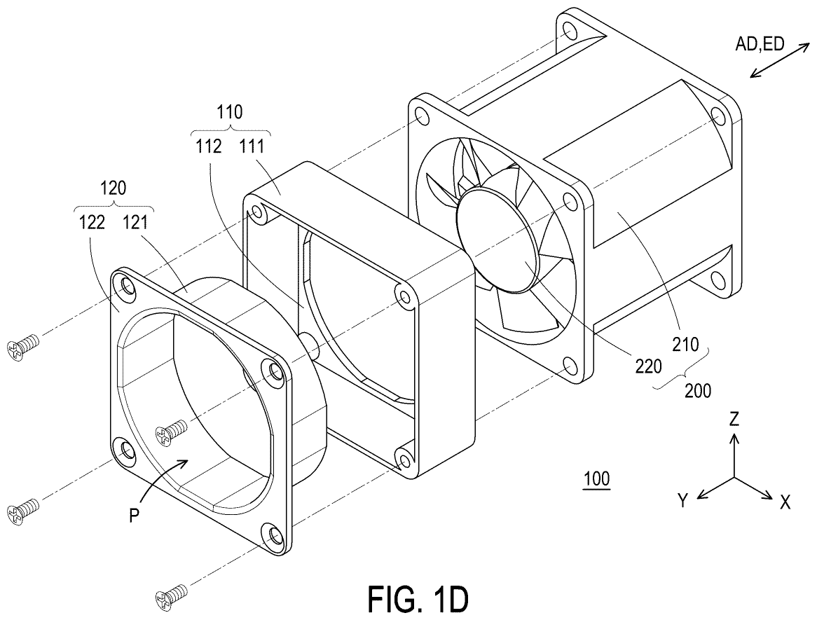

FIG. 1A is a three-dimensional schematic view of a silencing structure of an embodiment of the present invention. FIG. 1B is a cross-sectional schematic view of the silencing structure of FIG. 1A along segment A-A. FIG. 1C is a side planar schematic view of the silencing structure of FIG. 1A combined with a fan. FIG. 1D is an exploded three-dimensional schematic view of the components of the silencing structure and fan of FIG. 1C.

Referring to FIG. 1A and FIG. 1C, a silencing structure 100 of the present invention is suitable for combining with a server or other machines that operate for long periods of time. In brief, the silencing structure 100 adopts a Helmholtz resonator. When sound waves pass through the Helmholtz resonator, it can absorb part of the sound energy to achieve noise reduction effects.

Referring to FIG. 1A, FIG. 1B and FIG. 1D, the silencing structure 100 of this embodiment includes a silencing body 110, a silencing cover 120, and a fan module 200. The silencing body 110 has a first partition 111 and a neck partition 112. The first partition 111 is formed into a rectangular appearance surrounding the outer edge of the fan module 200, and the neck partition 112 is formed on the inner edge of the first partition 111, and the neck partition 112 is connected to the housing 210 of the fan module 200.

The silencing cover 120 is disposed on the silencing body 110 and has a second partition 121 and a fixed plate 122. The second partition 121 is parallel to the first partition 111 and surrounds to form a sound channel P, wherein the sound channel P is communicated with the neck partition 112. The fixed plate 122 is formed on the outer edge of the second partition 121 and covers the first partition 111.

Referring to FIG. 1A to FIG. 1C, a resonance cavity RC is constituted by the second partition 121, the fixed plate 122, and the first partition 111. A neck opening OP is formed between the second partition 121 and the neck partition 112. The neck opening OP is communicated with the resonance cavity RC and the sound channel P. Furthermore, the fan blade 220 of the fan module 200 is positioned in the sound channel P.

With reference to FIG. 1C and FIG. 1D, the neck opening OP is vertical to an extending direction ED (Y direction in FIG. 1A) of the sound channel P and an axial direction AD of the fan module 200. The neck opening OP surrounds the sound channel P, allowing the silencing cover 120 to capture the sound generated by the fan module 200 and transmitted through the sound channel P in a 360-degree manner.

Referring to FIG. 1C, a distance between the neck opening OP and the fan module 200 is a thickness of the neck partition 112, wherein the thickness of the neck partition 112 may be adjusted arbitrarily according to requirements, which is not limited in the present invention.

Referring to FIG. 1B and FIG. 1C, the cross-section of the first partition 111 and the neck partition 112 in an X direction is an L-shaped, and the cross-section of the second partition 121 and the fixed plate 122 in the X direction is L-shaped, thereby constituting the resonance cavity RC.

With reference to FIG. 1C, the neck opening OP and the resonance cavity RC surround the sound channel P, allowing the silencing structure 100 to extend only along the axial direction AD of the fan module 200, and an inner diameter of the sound channel P equals an inner diameter of the housing 210, therefore the silencing structure 100 will not change the airflow volume of the fan module 200, ensuring that the fan module 200 does not require structural modifications.

The silencing cover 120 and the silencing body 110 are installed on the fan module 200 of corresponding format, wherein the silencing cover 120 and the silencing body 110 are installed in the Y direction of the fan module 200, thus only increasing the volume in the Y direction, without affecting the X direction and Z direction of the fan module 200, and it is not easily noticeable in appearance.

Additionally, the silencing structure 100 of the present invention corresponding to the airflow channel FP of the fan module 200, without occupying space in the lateral or vertical direction of the airflow channel FP, thus not affecting the area of the airflow channel FP of the fan module 200.

Referring to FIG. 1C, when the fan module 200 operates, the fan blade 220 rotates along the Y direction and draws in airflow F and generates noise N, the airflow F is transmitted from the sound channel P to the airflow channel FP, and the noise N is transmitted from the airflow channel FP toward the sound channel P. When the noise N enters the sound channel P, part of the noise N enters the resonance cavity RC through the neck opening OP, and resonance attenuation is generated in the resonance cavity RC, thereby achieving the purpose of noise reduction.

Referring to FIG. 1D, the silencing body 110 and the silencing cover 120 of this embodiment are fixed to the housing 210 of the fan module 200 by screw connection, and in other embodiments, snap-fit or similar connection methods may be adopted.

Furthermore, the silencing body 110, the silencing cover 120, and the fan module 200 of the silencing structure 100 of this embodiment are mutually independent combined structures. Compared to the existing integrally formed silencing structure that is bound to fans of specific format, the silencing structure 100 of this embodiment may be combined with fans of different formats according to requirements. Since the mold cost and material cost of small-piece structures are both lower than the cost of large-piece structures, the silencing structure 100 of this embodiment adopts a plurality of independent small-piece structures, which can reduce costs in practical applications, therefore this embodiment has the advantages of saving mold costs and raw material costs.

Since each fan has different noise characteristics, the noise frequencies that need to be eliminated are also different. The silencing structure 100 of this embodiment may achieve the function of eliminating noise of different characteristic frequencies by replacing the first silencing body 110 or the silencing cover 120 in a simple replacement manner, therefore the silencing structure 100 of this embodiment is applicable to fans of various formats.

The following briefly explains the relationship between the structure of Helmholtz resonators and resonance frequency. Helmholtz resonators are composed of a resonance cavity and a neck.

The resonance frequency is proportional to the square root of the cross-sectional area of the neck opening OP, inversely proportional to the square root of the length of the neck opening OP, and inversely proportional to the square root of the volume of the resonance cavity RC. That is, the related parameters of the resonance frequency are the cross-sectional area of the neck opening OP, the length of the neck opening OP, and the volume of the resonance cavity RC. For example, the larger the volume of the resonance cavity RC, the longer the length of the neck opening OP, and the smaller the cross-sectional area of the neck opening OP, the lower the resonance frequency may be.

Therefore, the cross-sectional area of the neck opening OP, the length of the neck opening OP, and the volume of the resonance cavity RC may be adjusted arbitrarily according to usage requirements. As long as the proportions of the three parameters are the same, the Helmholtz resonator can be adjusted to the required resonance frequency.

With reference to FIG. 1C, when the neck opening OP is closer to the noise source, it may absorb the noise N earlier, reducing the number of reflections of the noise N in the sound channel P, and preventing the noise N from spreading outward.

In short, since the inner wall surface of the sound channel P causes multiple reflections of sound energy, concentrating the energy and making it difficult to attenuate, which is the main reason why the sound channel P can transmit sound to distant places, reducing the number of reflections of noise N in the sound channel P can make the noise N dissipate faster. Therefore, the neck opening OP should be placed near the fan module 200 to more effectively absorb the noise N and prevent the noise N from spreading.

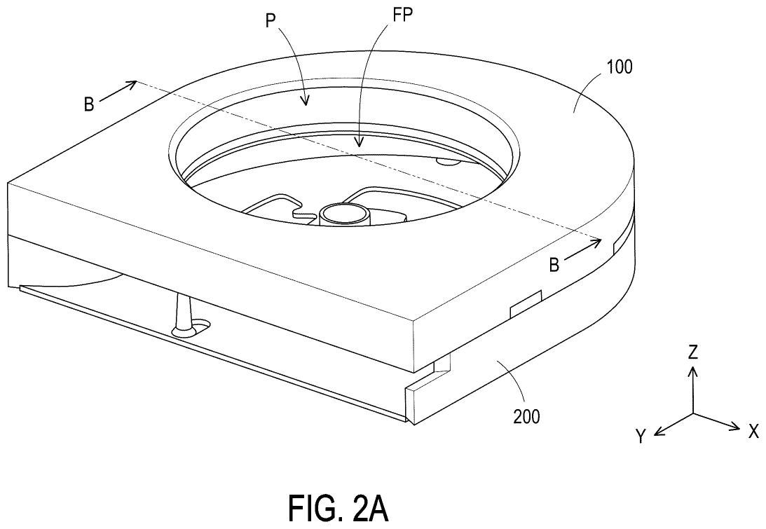

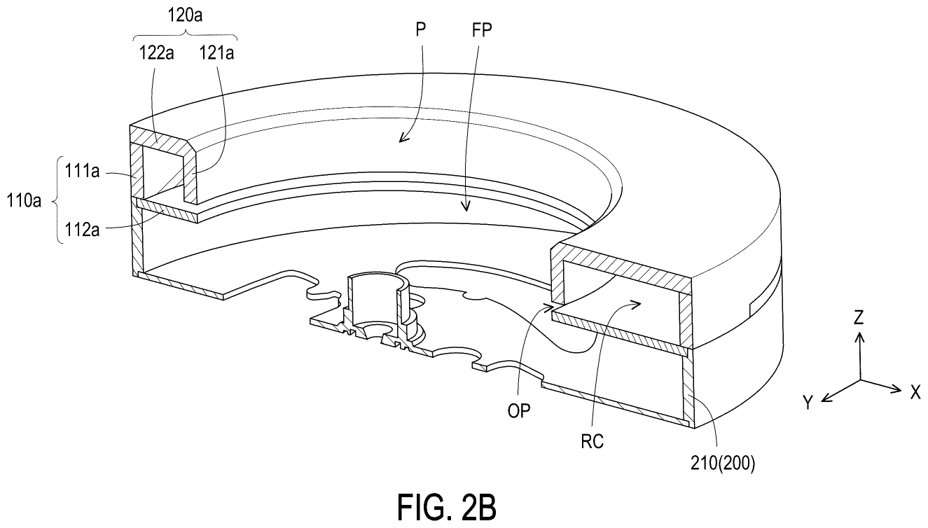

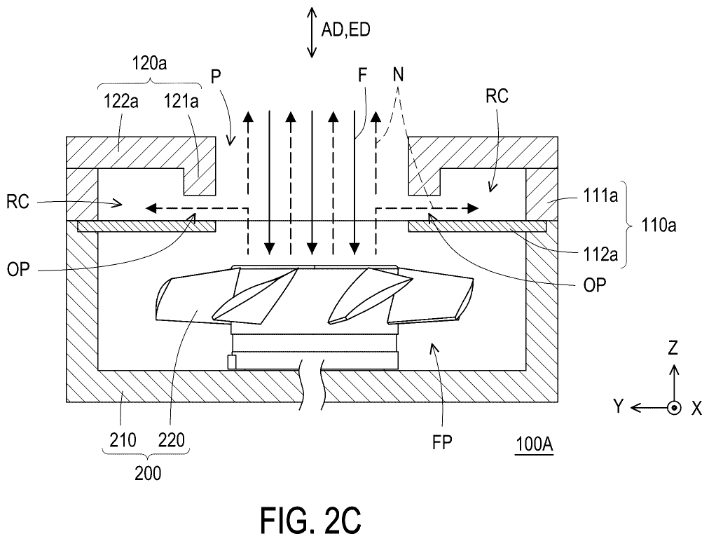

FIG. 2A is a three-dimensional schematic diagram of a silencing structure combined with a fan module according to another embodiment of this new creation. FIG. 2B is a cross-sectional schematic diagram along the B-B segment of the silencing structure of FIG. 2A. FIG. 2C is a cross-sectional schematic diagram along the C-C segment of the silencing structure of FIG. 2A.

Referring to FIG. 2A and FIG. 2B, the silencing structure 100A of this embodiment has a silencing body 110a and a silencing cover 120a.

The silencing body 110a has a first partition 111a and a neck partition 112a, and the silencing cover 120 has a second partition 121a and a top plate 122a, wherein the silencing body 110a is a U-shaped structure in a Z direction.

The first partition 111a is formed into a U-shaped appearance surrounding the outer edge of the fan module 200, and the neck partition 112a is formed on the inner edge of the first partition 111a, and the neck partition 112a partially covers the airflow channel FP in the Z direction of the fan module 200.

The silencing cover 120a is disposed on the silencing body 110a and has a second partition 121a and a top plate 122a. The second partition 121a is parallel to the first partition 111a and surrounds to form a sound channel P, wherein the sound channel P is communicated with the neck partition 112a. The top plate 122a is formed on the outer edge of the second partition 121a and covers the first partition 111a.

Referring to FIG. 2A to FIG. 2C, the second partition 121a, the top plate 122a, and the first partition 111a constitute a resonance cavity RC, and a neck opening OP is formed between the second partition 121a and the neck partition 112a. The neck opening OP is communicated with the resonance cavity RC and the sound channel P. Furthermore, the fan blade 220 of the fan module 200 is aligned with the sound channel P.

Referring to FIG. 2C, the sound channel P extends along the extending direction ED (Z direction in FIG. 2A), and the neck opening OP surrounds the sound channel P.

With reference to FIG. 2C, the neck opening OP and the resonance cavity RC surround the sound channel P, allowing the silencing structure 100A to only need to extend along the axial direction AD of the fan module 200.

The silencing cover 120a and the silencing body 110a are installed on the fan module 200 of corresponding format, wherein the silencing cover 120a and the silencing body 110a are installed in the Z direction of the fan module 200, thus only increasing the volume in the Z direction, without affecting the X direction and Y direction of the fan module 200, and are not easily noticeable in appearance.

Referring to FIG. 2C, when the fan module 200 operates, the fan blade 220 rotates along the Z direction and draws airflow F and generates noise N. The airflow F is transmitted from the sound channel P to the airflow channel FP, and the noise N is transmitted from the airflow channel FP toward the sound channel P. When the noise N enters the sound channel P, part of the noise N enters the resonance cavity RC through the neck opening OP, and resonance attenuation is generated in the resonance cavity RC, thereby achieving the purpose of noise reduction.

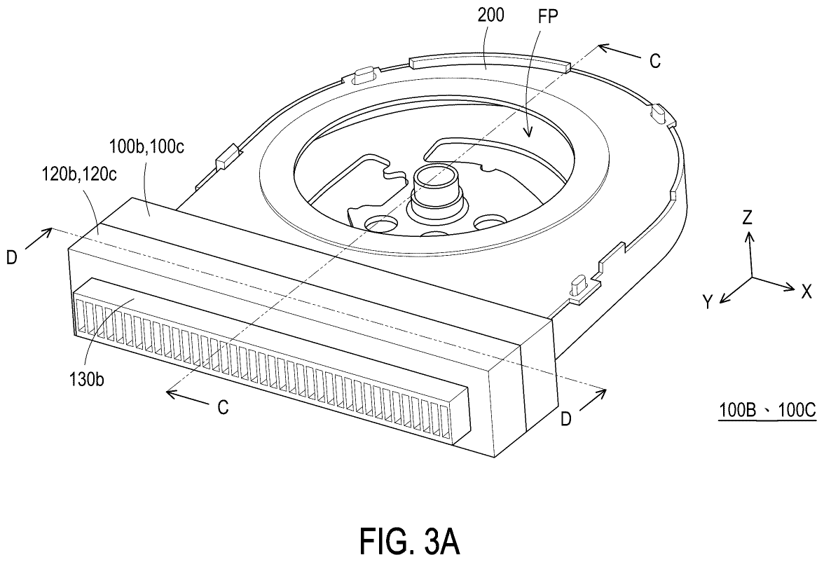

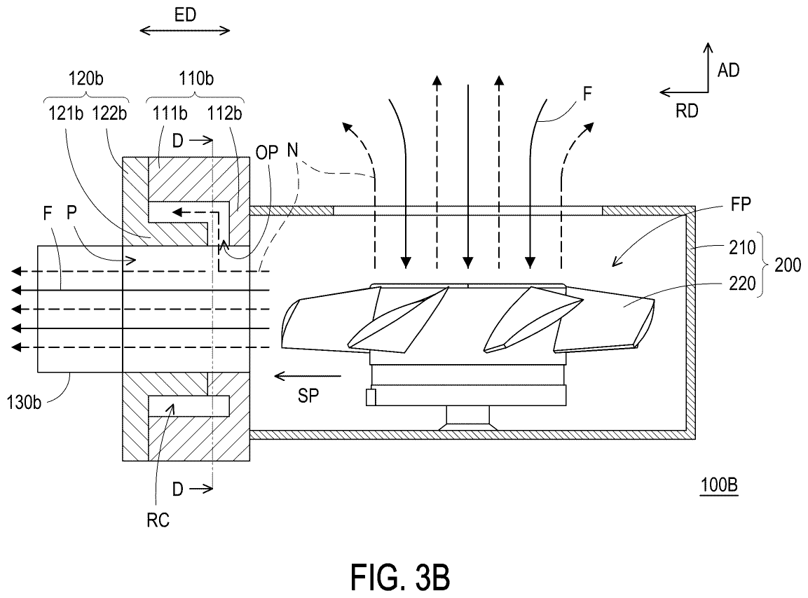

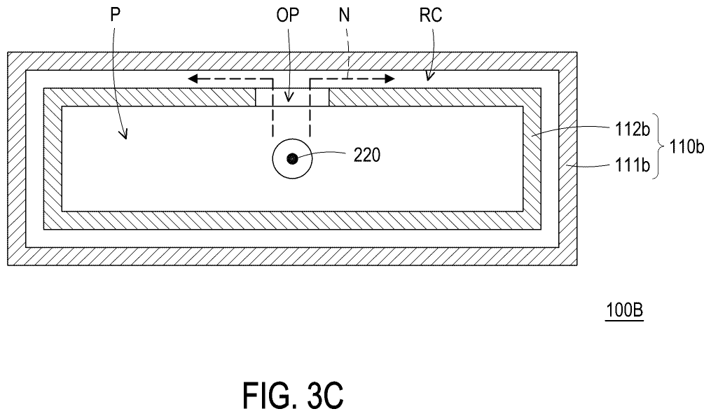

FIG. 3A is a three-dimensional schematic diagram of a silencing structure combined with a fan module and heat dissipation fins according to another embodiment of the present invention. FIG. 3B is a cross-section schematic diagram of the silencing structure of FIG. 3A along the C-C segment. FIG. 3C is a cross-section schematic diagram of the silencing structure of FIG. 3A along the D-D segment.

Referring to FIG. 3A to FIG. 3C, the silencing structure 100B of this embodiment has a silencing body 110b, a silencing cover 120b, and heat dissipation fins 130b.

The silencing body 110b has a first partition 111b and a neck partition 112b, the silencing cover 120b has a second partition 121b and a top plate 122a, wherein the silencing body 110b is rectangular structure in an extending direction ED (Y direction in FIG. 3A), and the axial direction AD of the fan module 200 is vertical to the extending direction ED of the sound channel P.

Referring to FIG. 3A and FIG. 3B, the silencing cover 120b or the silencing body 110b has an L-shaped cross-section in the direction vertical to the axial direction AD of the fan (along the C-C segment).

Referring to FIG. 3A and FIG. 3C, the silencing cover 120b or the silencing body 110b has a square cross-section in the direction vertical to the extending direction ED (along the D-D segment).

The first partition 111b is formed into a rectangular appearance surrounding the outer edge of the fan module 200, and the neck partition 112b is formed on the inner edge of the first partition 111b.

The silencing cover 120b is disposed on the silencing body 110b and has a second partition 121b and a top plate 122b. The second partition 121b is parallel to the first partition 111b and surrounds to form a sound channel P, wherein the sound channel P is communicated with the neck partition 112b. The top plate 122b is formed on the outer edge of the second partition 121b and covers the first partition 111b.

Additionally, the silencing cover 120b and the silencing body 110b are disposed at a side opening SP on the Y direction side of the fan module 200, and the neck partition 112b partially covers the side opening SP in the Y direction of the fan module 200.

Referring to FIG. 3B, the heat dissipation fins 130b are disposed on the silencing cover 120b and aligned with the sound channel P.

Referring to FIG. 3A to FIG. 3C, the second partition 121b, the top plate 122b, and the first partition 111b constitute a resonance cavity RC, and a neck opening OP is formed between the second partition 121b and the neck partition 112b. The neck opening OP is communicated with the resonance cavity RC and the sound channel P, wherein the neck opening OP is vertical to the extending direction ED of the sound channel P and the radial direction RD of the fan module 200.

Referring to FIG. 3B, the sound channel P extends along the extending direction ED (Y direction in FIG. 3A), and the neck opening OP only communicates with one location of the sound channel P.

With reference to FIG. 3B and FIG. 3C, the neck opening OP and the resonance cavity RC surround the sound channel P, allowing the silencing structure 100B to only extend along the axial direction AD of the fan module 200. The silencing cover 120b and the silencing body 110b are installed on a fan module 200 of corresponding format, wherein the silencing cover 120b and the silencing body 110b are installed in the Y direction of the fan module 200.

Referring to FIG. 3B and FIG. 3C, when the fan module 200 operates, the fan blade 220 rotates along the Z direction and generates airflow F and noise N. Part of the airflow F and noise N are transmitted along the Y direction from the side opening SP toward the sound channel P. When the noise N enters the sound channel P, part of the noise N passes through the neck opening OP to enter the resonance cavity RC, and resonance attenuation is generated in the resonance cavity RC, thereby achieving the purpose of noise reduction.

Moreover, the airflow F entering the sound channel P may be cooled after passing through the heat dissipation fins 130b, and the cooled airflow F may perform secondary circulation in the server, which is beneficial for improving heat dissipation efficiency.

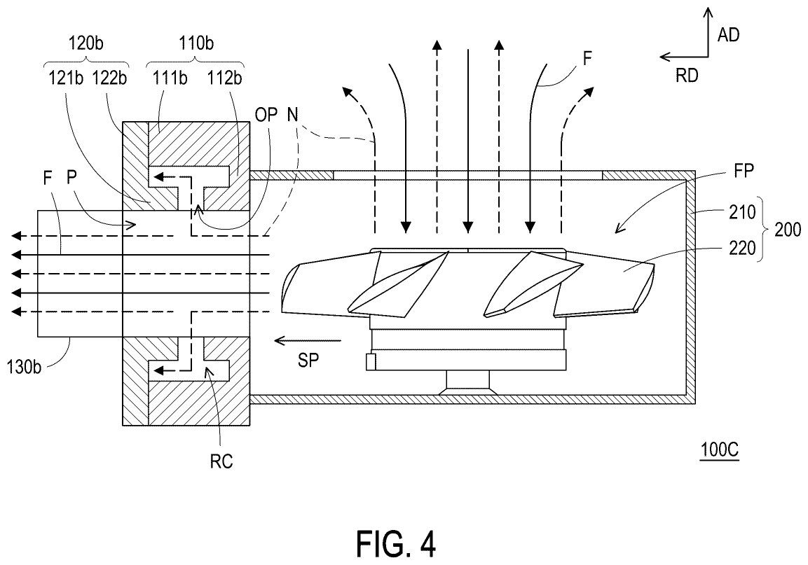

FIG. 4 is a cross-section view along the C-C segment of another embodiment of the silencing structure of FIG. 3A.

Referring to FIG. 4, the silencing structure 100C of this embodiment is similar to the silencing structure 100B of FIG. 3A, with the difference being that the second partition 121c, the top plate 122c, and the first partition 111c of the silencing structure 100C constitute a resonance cavity RC, and a neck opening OP is formed between the second partition 121c and the neck partition 112c. The neck opening OP is communicated with the resonance cavity RC and the sound channel P, wherein the neck opening OP is vertical to an extending direction ED of the sound channel P and a radial direction RD of the fan module.

Referring to FIG. 4, the sound channel P extends along the Y direction and the neck opening OP surrounds the sound channel P.

Furthermore, the silencing structure 100 of the present case is suitable for combining with a server. The server includes a chassis, at least one heat-generating component, and a plurality of silencing structures. The at least one heat-generating component is disposed inside the chassis. The plurality of silencing structures are arranged in a matrix or stacked in a matrix inside the chassis, and partially or completely correspond to the at least one heat-generating component.

Specifically, the at least one heat-generating component includes at least one central processing unit, at least one graphics processing unit, at least one neural processor, at least one memory, at least one hard disk, at least one solid-state drive, at least one power supply, or at least one main circuit board. In other embodiments, the at least one heat-generating component includes a plurality of components that respectively correspond to a plurality of silencing structures to achieve the effect of vibration reduction and noise resistance.

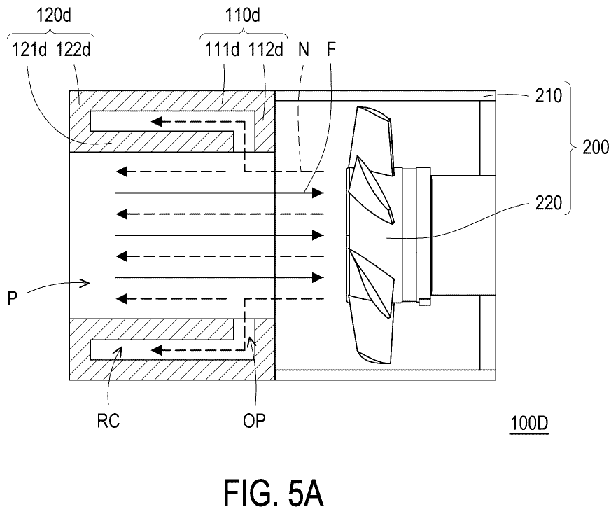

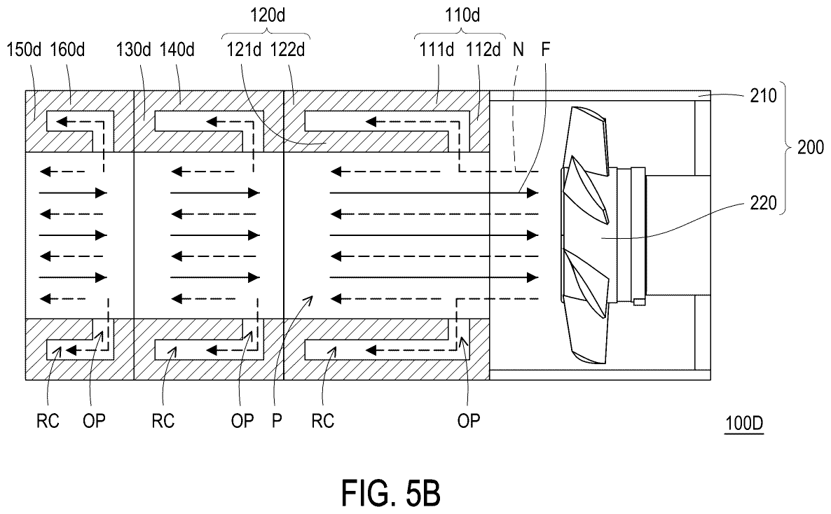

FIG. 5A is a cross-section view of another embodiment of the silencing structure of the present utility model combined with a fan and heat dissipation fins. FIG. 5B is a cross-section view of the silencing structure of FIG. 5A combined with a first silencing body, a first silencing cover, a second silencing body, and a second silencing cover.

Referring to FIG. 5A, the silencing structure 100D of this embodiment includes a silencing body 110d and a silencing cover 120d.

The silencing body 110d is disposed on the silencing cover 120d and has a first partition 111d and a neck partition 112d. The fan module 200 is connected to the silencing body 110d. The first partition 111d is formed into a rectangular appearance surrounding the outer edge of the fan module 200, and the neck partition 112d is formed on the inner edge of the first partition 111d, with the neck partition 112d connected to the housing 210 of the fan module 200.

The silencing cover 120d has a fixed plate 122d and a second partition 121d, the fixed plate 122d corresponded to the neck partition 112d, and the second partition 121d is connected to the fixed plate 122d. In this embodiment, the silencing cover 120d and the silencing body 110d are formed as an integrated structure.

Wherein, a neck opening OP is formed between the silencing cover 120d and the neck partition 112d. Additionally, the first partition 111d of the silencing body 110d corresponded to the second partition 121d of the silencing cover 120d and is connected to the neck partition 112d, thereby forming the neck opening OP between the second partition 121d and the neck partition 112d.

A resonance cavity RC is formed between the silencing cover 120d and the silencing body 110d, communicating with the neck opening OP. Specifically, the resonance cavity RC is formed among the second partition 121d, the fixed plate 122d, the first partition 111d, and the neck partition 112d.

Referring to FIG. 5A, the fan module 200, the silencing body 110d, and the silencing cover 120d surround to form a sound channel P, and the neck opening OP is communicated with the resonance cavity RC and the sound channel P. In this embodiment, the neck opening OP surrounds the sound channel P, and the resonance cavity RC surrounds the sound channel P.

With reference to FIG. 5A, the silencing structure 100D of this embodiment is suitable for adjusting dimensional parameters as follows: the distance between the neck opening OP and the fan module 200 is less than or equal to the length of the silencing cover 120d and the silencing body 110d. The distance between the neck opening OP and the fan module 200 is less than or equal to the length of the silencing body 110d. The distance between the neck opening OP and the fan module 200 is less than or equal to the length of the neck partition 112d. The distance between the neck opening OP and the fan module 200 is less than or equal to the thickness of the neck partition 112d. Furthermore, the length of the silencing cover 120d is less than or equal to the length of the silencing body 110d, or the length of the silencing body 110d is less than or equal to the length of the silencing cover 120d.

Referring to FIG. 5B, the silencing structure 100D of this embodiment further includes a first silencing cover 130d, a first silencing body 140d, a second silencing cover 150d, and a second silencing body 160d. The first silencing body 140d is connected to the first silencing cover 130d and stacked on the silencing cover 120d, the second silencing body 160d is connected to the second silencing cover 150d and stacked on the first silencing cover 130d, thereby increasing the length of the sound channel P and providing a plurality of resonance cavities RC and a plurality of neck openings OP, thus enhancing the effect of noise reduction.

In this embodiment, the length of the silencing cover 120d is greater than or equal to the length of the first silencing cover 130d, and the length of the first silencing cover 130d is greater than or equal to the length of the second silencing cover 150d, meaning the sizes decrease as they move away from the fan module. In other embodiments, the length of the silencing cover may be less than or equal to the length of the first silencing cover, and the length of the first silencing cover may be less than or equal to the length of the second silencing cover, meaning the sizes increase as move away from the fan module, depending on the structural requirements.

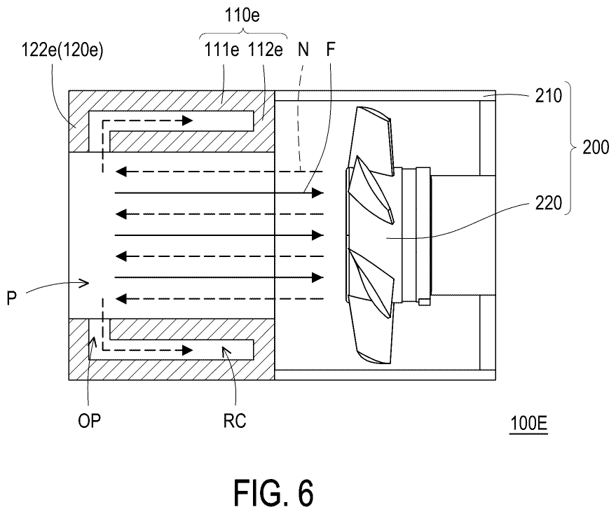

FIG. 6 is a cross-section diagram illustrating another embodiment of the silencing structure of the present invention combined with a fan and heat dissipation fins.

Referring to FIG. 5B, the silencing structure 100E of this embodiment includes a silencing body 110e and a silencing cover 120e. The silencing cover 120e has a fixed plate 122e, and the silencing body 110e is disposed on the silencing cover 120e and has a first partition 111e and a neck partition 112e. The neck partition 112e extends toward the fixed plate 122e and is parallel to the first partition 111e, thereby forming a neck opening OP between the fixed plate 122e and the neck partition 112e, and forming a resonance cavity RC between the fixed plate 122e, the first partition 111e, and the neck partition 112e.

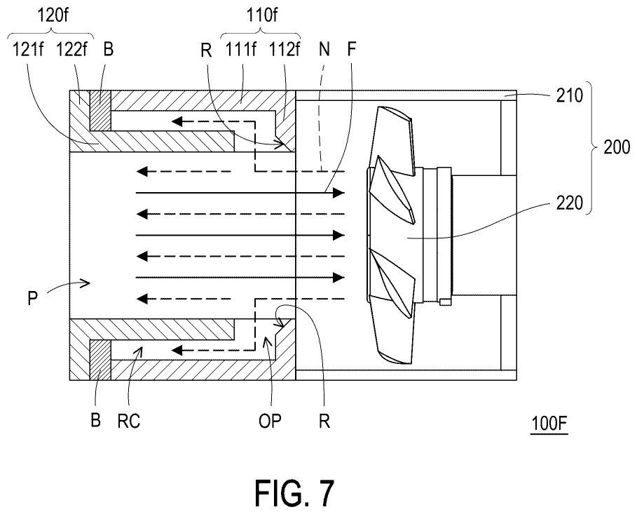

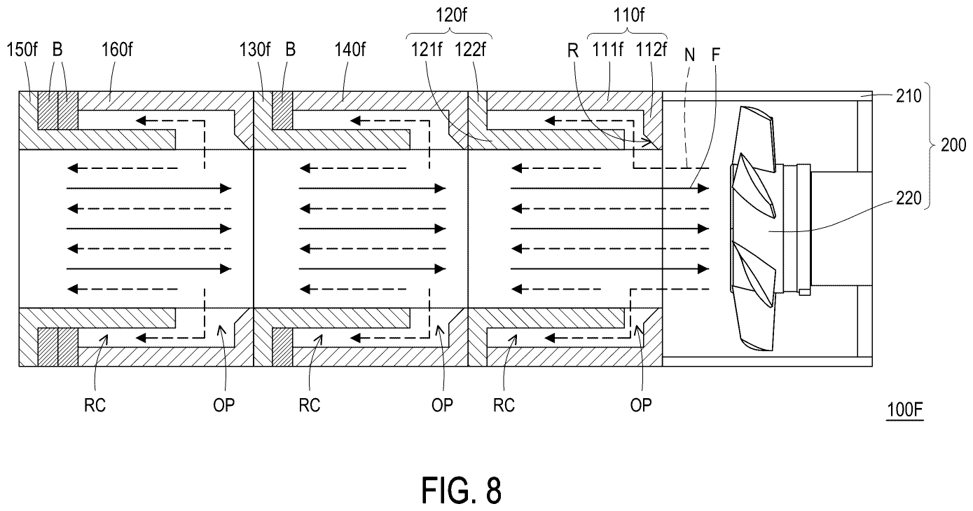

FIG. 7 is a cross-section diagram illustrating another embodiment of the silencing structure of the present invention combined with a fan and heat dissipation fins. FIG. 8 is a cross-section diagram illustrating the silencing structure of FIG. 7 combined with a first silencing body, a first silencing cover, a second silencing body, a second silencing cover, and a plurality of washers.

Referring to FIG. 7, the silencing structure 100F of this embodiment further includes at least one washer 130f, disposed between the fixed plate 122f of the silencing cover 120f and the first partition 111f of the silencing body 110f to adjust the dimensions of the neck opening OP and the resonance cavity RC. In addition, the neck partition 112f has a chamfer R corresponding to the second partition 121f of the silencing cover 120f. The chamfer R is suitable for changing the shape of the neck opening OP, thereby absorbing noise of different frequencies.

Referring to FIG. 8, the silencing structure 100F of this embodiment further includes a first silencing cover 130f, a first silencing body 140f, a second silencing cover 150f, and a second silencing body 160f. The first silencing body 140f is connected to the first silencing cover 130f and is stacked on the silencing cover 120f, and the second silencing body 160f is connected to the second silencing cover 150f and is stacked on the first silencing cover 130f. Therefore, increasing the length of the sound channel P and provides a plurality of resonance cavities RC and a plurality of neck openings OP, thereby enhancing the effect of noise reduction.

Wherein, no washer B is used between the silencing cover 120f and the silencing body 110f, one washer B is disposed between the first silencing cover 130f and the first silencing body 140f, and two washers B are disposed between the second silencing cover 150f and the second silencing body 160f, allowing differences in sizes among the plurality of neck openings OP and a plurality of resonance cavities RC, thereby absorbing noise of different frequencies.

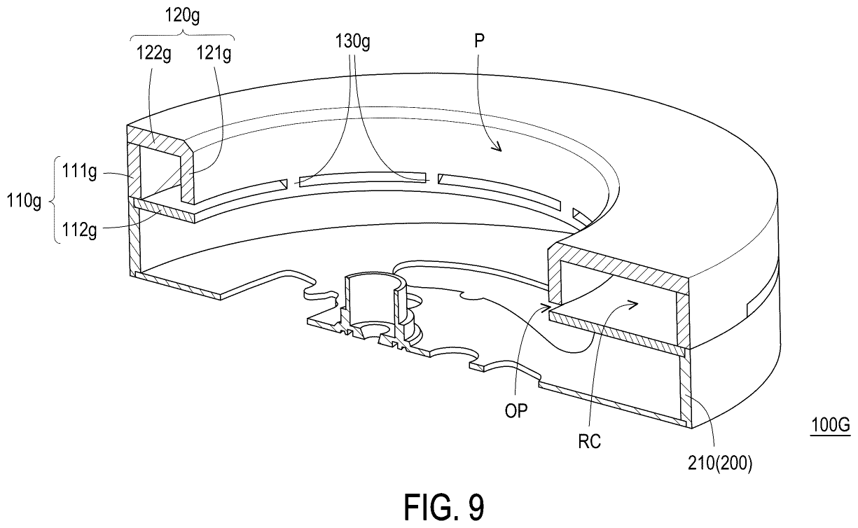

FIG. 9 is a cross-section diagram of another embodiment of the silencing structure of FIG. 2A along the B-B segment.

Referring to FIG. 9, the silencing structure 100G of this embodiment has a silencing body 110g, a silencing cover 120g, and a plurality of ribs 130g. The silencing body 110g has a first partition 111g and a neck partition 112g, and the silencing cover 120g has a second partition 121g and a top plate 122g. The plurality of ribs 130g connect between the second partition 121g of the silencing cover 120g and the neck partition 112g of the silencing body 110g. The plurality of ribs 130g are used to adjust or reduce the frequency of the neck opening OP and the resonance cavity RC.

In summary, the silencing structure of this new creation is applicable to existing fan modules. By controlling the cross-sectional area of the resonance cavity and the length of the neck opening, the resonance frequency of the silencing structure may approach the vibration frequency of the noise. When noise passes through the silencing structure, part of the noise enters the resonance cavity through the neck opening to produce energy attenuation, thereby reducing the sound energy during noise transmission and achieving the purpose of noise reduction.

In addition, the silencing structure of this new creation may be directly installed on existing fan modules without changing the orientation of cooling components in servers or supercomputers, thereby having better versatility.

The silencing structure of the present invention is applicable to server rooms, thereby reducing the impact of fan noise on traditional hard drives and future high-capacity disk hard drives, improving their reading performance; while also avoiding the risk of possible operational stoppage when they are exposed to high-decibel noise for extended periods.

The silencing structure of the present invention is suitable for application in AI full-cabinet server systems where cooling fans are arranged in horizontal and vertical direction matrices.

Furthermore, the silencing structure of the present invention may reduce noise in server rooms, improving the working environment for server room personnel, which aligns with the spirit of various modern occupational health and safety trends and initiatives, such as: ESG, DEI, OHS & Green IT.

The noise in server rooms is typically between 70 and 90 decibels. Long-term exposure to this noise range may lead to hearing damage, increased stress, headaches, and even affect the cardiovascular system.

Relation to Social in ESG: Providing a healthy and safe working environment, improving employee well-being, reducing occupational diseases and work-related accidents, while taking social responsibility, paying attention to employees'working conditions, and enhancing employee satisfaction and loyalty.

Relation to Equity in DEI: Providing equal health and safety protection measures, ensuring all employees receive fair treatment in the working environment.

Relation to OHS: Taking appropriate measures to reduce the risk of employees'long-term exposure to noise.

Relation to Green IT: Using low-noise server systems to reduce noise pollution.

What is claimed is:

1. A silencing structure, comprising:
a fan module;
a silencing body, having a first partition and a neck partition, the neck partition connecting to the fan module; and
a silencing cover, disposed on the silencing body and having a second partition and a fixed plate, the fan module, the silencing body and the silencing cover surrounding to form a sound channel,
wherein, a resonance cavity is constituted by the second partition, the fixed plate and the first partition, a neck opening is formed between the second partition and the neck partition, and the neck opening is communicated with the resonance cavity and the sound channel.

2. A silencing structure, comprising:
a silencing cover; and
a silencing body, disposed on the silencing cover, and having a neck partition;
wherein, a neck opening is formed between the silencing cover and the neck partition, a resonance cavity is formed between the silencing cover and the silencing body, communicated with the neck opening.

3. The silencing structure as claimed in claim 2, wherein the silencing cover and the silencing body are integrally formed.

4. The silencing structure as claimed in claim 2, wherein the silencing cover has a fixed plate and a second partition, the fixed plate is corresponded to the neck partition, and the second partition is connected to the fixed plate.

5. The silencing structure as claimed in claim 4, wherein the silencing body has a first partition, corresponding to the second partition, and connecting to the neck partition.

6. The silencing structure as claimed in claim 4, wherein the neck opening is formed between the second partition and the neck partition.

7. The silencing structure as claimed in claim 5, wherein the neck opening is formed between the fixed plate and the neck partition.

8. The silencing structure as claimed in claim 5, wherein the resonance cavity is formed among the second partition, the fixed plate, the first partition and the neck partition.

9. The silencing structure as claimed in claim 5, wherein the resonance cavity is formed among the fixed plate, the first partition and the neck partition.

10. The silencing structure as claimed in claim 5, further comprising a fan module, connected to the silencing body.

11. The silencing structure as claimed in claim 10, wherein a distance between the neck opening and the fan module is less than or equal to a length of the silencing cover and the silencing body.

12. The silencing structure as claimed in claim 10, wherein a distance between the neck opening and the fan module is less than or equal to a length of the silencing body.

13. The silencing structure as claimed in claim 10, wherein a distance between the neck opening and the fan module is less than or equal to a length of the neck partition.

14. The silencing structure as claimed in claim 10, wherein a distance between the neck opening and the fan module is less than or equal to a thickness of the neck partition.

15. The silencing structure as claimed in claim 10, wherein the fan module, the silencing body and the silencing cover are surrounded to form a sound channel, and the neck opening is communicated with the resonance cavity and the sound channel.

16. The silencing structure as claimed in claim 15, wherein the neck opening surrounds the sound channel.

17. The silencing structure as claimed in claim 15, wherein the resonance cavity surrounds the sound channel.

18. The silencing structure as claimed in claim 2, wherein a length of the silencing cover is less than or equal to a length of the silencing body.

19. The silencing structure as claimed in claim 2, wherein a length of the silencing body is less than or equal to a length of the silencing cover.

20. The silencing structure as claimed in claim 2, further comprising a first silencing cover, a first silencing body, a second silencing cover and a second silencing body, the first silencing body is connected to the first silencing cover and stacked on the silencing cover, the second silencing body is connected to the second silencing cover and stacked on the first silencing cover.

21. The silencing structure as claimed in claim 20, wherein a length of the silencing cover is less than or equal to a length of the first silencing cover, and the length of the first silencing cover is less than or equal to the length of the second silencing cover.

22. The silencing structure as claimed in claim 20, wherein a length of the silencing cover is greater than or equal to a length of the first silencing cover, and the length of the first silencing cover is greater than or equal to the length of the second silencing cover.

23. The silencing structure as claimed in claim 2, further comprising at least one washer disposed between the silencing cover and the silencing body.

24. The silencing structure as claimed in claim 2, wherein the neck partition has a chamfer, and the chamfer is corresponding to the silencing cover.

25. The silencing structure as claimed in claim 2, further comprising a plurality of ribs connected between the silencing cover and the neck partition.

26. A server, comprising:
a chassis;
at least one heat-generating component, disposed in the chassis; and
a plurality of silencing structures as claimed in claim 1, matrix arranged or matrix stacked in the chassis, and partially or completely corresponding to the at least one heat-generating component.
